(19) United States
(12) Patent Application Publication
(10) Pub. No.: US 2026/0006793 A1
(43) Pub. Date: Jan. 1, 2026

(54) SEMICONDUCTOR DEVICE INCLUDING FERROELECTRIC LAYER AND PARAELECTRIC LAYER

(71) Applicant: Samsung Electronics Co., Ltd., Suwon-si (KR)

(72) Inventors: Haeyeon JUN, Suwon-si (KR); Chang-Soo LEE, Suwon-si (KR); Jisung KIM, Suwon-si (KR); Jaewoo PARK, Suwon-si (KR); Junnoh LEE, Suwon-si (KR)

(73) Assignee: Samsung Electronics Co., Ltd., Suwon-si (KR)

(21) Appl. No.: 19/032,590

(22) Filed: Jan. 21, 2025

(30) Foreign Application Priority Data
Jun. 27, 2024 (KR) 10-2024-0084410

(51) Int. Cl. H10B 51/30; H01L 23/00; H01L 25/16; H10B 41/27; H10B 41/30; H10B 43/27; H10B 43/30; H10B 51/20; H10B 80/00

(52) U.S. Cl. CPC H10B 51/30; H01L 25/16; H10B 41/27; H10B 41/30; H10B 43/27; H10B 43/30; H10B 51/20; H10B 80/00; H01L 24/32; H01L 24/48; H01L 24/73; H01L 2224/32145; H01L 2224/32225; H01L 2224/48091; H01L 2224/48147; H01L 2224/48227; H01L 2224/73265; H01L 2225/06506; H01L 2225/0651; H01L 2225/06562; H01L 2924/1438

(57) ABSTRACT

Provided is a semiconductor device including a substrate, a stacked structure including a plurality of gate electrodes and a plurality of interlayer insulating layers, and a plurality of channel structures penetrating the stacked structure. Each of the plurality of channel structures includes a channel poly layer, a crystalline layer including hafnium (Hf) or zirconium (Zr), an electron trap layer, and a plurality of gate insulating layers positioned between the electron trap layer and the plurality of gate electrodes at a height corresponding to the plurality of gate electrodes. The crystalline layer includes a plurality of ferroelectric layers positioned at a height corresponding to the plurality of gate electrodes, and a plurality of paraelectric layers positioned at a height corresponding to the plurality of interlayer insulating layers. The plurality of ferroelectric layers and the plurality of paraelectric layers have different crystal structures while containing the same material.

### CROSS-REFERENCE TO RELATED APPLICATION

This application claims the benefit of Korean Patent Application No. 10-2024-0084410 filed on Jun. 27, 2024, in the Korean Intellectual Property Office, the entire disclosure of which is incorporated herein by reference for all purposes.

### BACKGROUND

### 1. Field of the Invention

One or more embodiments relate to a semiconductor device including a ferroelectric layer and a paraelectric layer.

### 2. Description of the Related Art

There is a demand for a semiconductor device capable of storing a large amount of data in an electronic system that utilize data storage. Therefore, methods to increase the data storage capacity of a semiconductor device have been studied. For example, one of the methods to increase the data storage capacity of a semiconductor device proposes a semiconductor device including three-dimensionally arranged memory cells instead of two-dimensionally arranged memory cells.

### SUMMARY

According to an aspect, there is provided a semiconductor device including a substrate, a stacked structure comprising a plurality of gate electrodes and a plurality of interlayer insulating layers alternately stacked on the substrate; and a plurality of channel structures penetrating the stacked structure, wherein each of the plurality of channel structures comprises a channel poly layer, a crystalline layer outside the channel poly layer and comprising at least one of hafnium (Hf) or zirconium (Zr), an electron trap layer outside the crystalline layer such that the crystalline layer is between the electron trap layer and the channel poly layer, and a plurality of gate insulating layers between the electron trap layer and the plurality of gate electrodes at heights corresponding to the plurality of gate electrodes, wherein the crystalline layer comprises a plurality of ferroelectric layers each at a height corresponding to one of the plurality of gate electrodes, and a plurality of paraelectric layers each at a height corresponding to one of the plurality of interlayer insulating layers, and the plurality of ferroelectric layers and the plurality of paraelectric layers have different crystal structures while containing the same material.

An inner end portion of each of the plurality of interlayer insulating layers protrudes toward a center of a corresponding one of the plurality of channel structures from an inner end portion of a corresponding one of the plurality of gate electrodes.

An inner end portion of the corresponding gate insulating layer may protrude inward further than the inner end portion of corresponding interlayer insulating layer, and an outer end portion of the corresponding gate insulating layer may be further outward compared to the inner end portion of the corresponding interlayer insulating layers.

The electron trap layer may comprise a plurality of first electron trap layer portions at heights corresponding to the plurality of gate electrodes, and a plurality of second electron trap layer portions positioned at heights corresponding to the plurality of interlayer insulating layers. The plurality of first electron trap layer portions may be further inward compared to the plurality of second electron trap layer portions.

A radius from a center of each of the plurality of channel structures to an outer end portion of the plurality of paraelectric layers may be greater than a radius from the center of the channel structure to an outer end portion of the plurality of ferroelectric layers.

A difference between the radius from the center of the channel structure to the outer end portion of the plurality of paraelectric layers and the radius from the center of the channel structure to the outer end portion of the plurality of ferroelectric layers may be 30 Å or less.

A difference between the radius from the center of the channel structure to the outer end portion of the plurality of paraelectric layers and the radius from the center of the channel structure to the outer end portion of the plurality of ferroelectric layers may be with a range of 100 Å to 300 Å.

A thickness of the ferroelectric layer may be greater than a thickness of the gate electrode.

Each of the plurality of paraelectric layers may include a first paraelectric layer portion defined by a corresponding one of the plurality of second electron trap layer portions, and a second paraelectric layer portion extending inward from a corresponding one of the plurality of first paraelectric layer portion and having a thickness, in a vertical direction, greater than a thickness of the first paraelectric layer portion.

The thickness of the second paraelectric layer may be smaller than a thickness of the corresponding interlayer insulating layer.

The ferroelectric layers may have an orthorhombic crystal structure, and the paraelectric layers may have a monoclinic crystal structure.

The crystalline layer may include at least one of Hf₁₋ₓZrₓO₂ (0≤x≤1), or doped Hf₁₋ₓZrₓO₂ (0≤x≤1) doped with at least one of aluminum (Al), carbon (C), nitrogen (N), gadolinium (Gd), yttrium (Y), tantalum (Ta), lanthanum (La), or silicon (Si).

The semiconductor device may further include a channel insulating layer between the channel poly layer and the crystalline layer.

The channel insulating layer may include a high-k material.

A thickness of each of the plurality of gate insulating layers may be the same as a thickness of a corresponding one of the plurality of gate electrodes.

According to another aspect, there is provided a semiconductor device including a substrate, a stacked structure comprising a plurality of gate electrodes and a plurality of interlayer insulating layers alternately stacked on the substrate; and a plurality of channel structures penetrating the stacked structure, wherein each of the plurality of channel structures comprises a channel poly layer, a crystalline layer outside the channel poly layer and comprising at least one of hafnium (Hf) or zirconium (Zr), and a plurality of gate insulating layers between the crystalline layer and the plurality of gate electrodes at heights corresponding to the plurality of gate electrodes, wherein the crystalline layer comprises a plurality of ferroelectric layers each at a height corresponding to the plurality of gate electrodes, and a plurality of paraelectric layers each at a height corresponding to the plurality of interlayer insulating layers, and the plurality of ferroelectric layers and the plurality of paraelectric layers have different crystal structures while containing the same material.

An inner end portion of each of the plurality of interlayer insulating layers may protrude toward a center of a corresponding one of the plurality of channel structures from an inner end portion of a corresponding one of the plurality of gate electrodes.

An inner end portion of the corresponding gate insulating layers protrudes further inward further than the inner end portion of the plurality of interlayer insulating layers, and an outer end portion of the corresponding gate insulating layers is further outward compared to the inner end portion of the corresponding interlayer insulating layer.

A radius from a center of each of the plurality of channel structure to an outer end portion of the plurality of paraelectric layers may be greater than a radius from the center of the channel structure to an outer end portion of the plurality of ferroelectric layers.

Each of the plurality of paraelectric layers may include a first paraelectric layer portion inside the interlayer insulating layer, and a second paraelectric layer portion extending inward from the first paraelectric layer portion and having a thickness greater than a thickness of the first paraelectric layer portion.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram schematically illustrating an electronic system including a semiconductor device according to at least one of the present disclosure;

FIG. 2 is a perspective view schematically illustrating an electronic system including a semiconductor device according to at least one of the present disclosure;

FIG. 3 is a cross-sectional view schematically illustrating a semiconductor package according to at least one;

FIG. 4 is a cross-sectional view of a cell array area of a semiconductor device according to at least one;

FIG. 5 is an enlarged cross-sectional view illustrating a channel structure of a semiconductor device according to at least one;

FIGS. 6A to 6G are partial cross-sectional views illustrating a process of manufacturing a channel structure according to at least one;

FIG. 7 is an enlarged cross-sectional view illustrating a channel structure of a semiconductor device according to at least one;

FIGS. 8A to 8C are partial cross-sectional views illustrating a process of manufacturing a channel structure according to at least one;

FIG. 9A is an enlarged cross-sectional view illustrating a channel structure of a semiconductor device according to at least one;

FIG. 9B is an enlarged cross-sectional view illustrating a channel structure of a semiconductor device according to at least one; and

FIG. 9C is an enlarged cross-sectional view illustrating a channel structure of a semiconductor device according to at least one.

### DETAILED DESCRIPTION

Hereinafter, the examples will be described in detail with reference to the accompanying drawings. When describing the examples with reference to the accompanying drawings, like reference numerals refer to like elements and a repeated description related thereto will be omitted.

The terminology used herein is for the purpose of describing particular embodiments only and is not to be limiting of the embodiments. The singular forms “a,” “an,” and “the” are intended to include the plural forms as well, unless the context clearly indicates otherwise.

It will be further understood d that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. Additionally, unless indicated otherwise, functional elements that process at least one function or operation may be implemented in processing circuitry such as hardware, software, and/or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, the terms first, second, A, B, (a), and (b) may be used to describe constituent elements of the embodiments. These terms are used only for the purpose of discriminating one component from another component, and the nature, the sequences, or the orders of the components are not limited by the terms. It should be noted that if it is described that one component is “connected”, “coupled”, or “joined” to another component, a third component may be “connected”, “coupled”, and “joined” between the first and second components, although the first component may be directly connected, coupled, or joined to the second component.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

It is understood that the term “about” indicates a range of numbers to be considered by those skilled in the art to be equivalent to the described value in terms of achieving the same function or result. When the term “about” is used with a number or a value, the term “about” refers to ±20% of the number or the value, often ±10% of the number or the value, usually ±5% of the number or the value, or ±2% of the number or the value. In some embodiments, the term “about” may refer to the number or value itself. Similarly, the term “substantially” is to be considered by those skilled in the art to be equivalent to the described value in terms of achieving the same function or result. Additionally, whenever a range of values is enumerated, the range includes all values within the range as if recorded explicitly clearly, and may further include the boundaries of the range. Accordingly, the range of “X” to “Y” includes all values between X and Y, including X and Y.

As used herein, “A or B”, “at least one of A and B”, “at least one of A or B”, “A, B or C”, “at least one of A, B and C”, and “at least one of A, B, or C,” may include any one of the items listed together in the corresponding one of the phrases, or all possible combinations thereof.

Hereinafter, terms “upper” or “top” or “lower” or “bottom” may include not only those directly above/below/left/right in contact, but also those above/below/left/right without contact. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

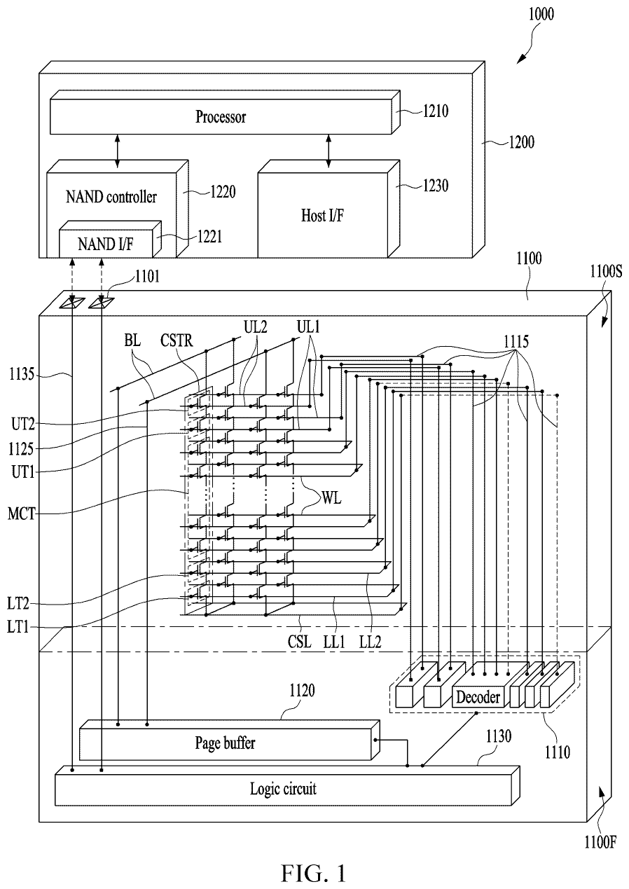

FIG. 1 is a diagram schematically illustrating an electronic system including a semiconductor device according to at least one of the present disclosure.

Referring to FIG. 1, in at least one, an electronic system 1000 may include a semiconductor device 1100 and a controller 1200 electrically connected to the semiconductor device 1100. The electronic system 1000 may be a storage device that includes a single or a plurality of semiconductor devices 1100 and/or may be an electronic device that includes the storage device. For example, the electronic system 1000 may be a solid-state drive (SSD) device, a Universal Serial Bus (USB), a computing system, a medical device, a communication device, and/or the like, each of which includes a single or a plurality of semiconductor devices 1100.

The semiconductor device 1100 may be a nonvolatile memory device, such as a NAND flash memory device. The semiconductor device 1100 may include a first structure 1100F and a second structure 1100S on the first structure 1100F. The first structure 1100F may be arranged next to the second structure 1100S.

The first structure 1100F may be a peripheral circuit structure that includes a decoder circuit 1110, a page buffer 1120, and a logic circuit 1130. The second structure 1100S may be a memory cell structure that includes bit lines BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary according to embodiments.

The upper transistors UT1 and UT2 may include a string selection transistor. The lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT. The gate upper lines UL1 and UL2 may be gate electrodes of the upper transistors UT1 and UT2, respectively.

The lower transistors LT1 and LT2 may include a lower erase control transistor LT1 and a ground selection transistor LT2 that are connected in series. The upper transistors UT1 and UT2 may include a string selection transistor UT1 and an upper erase control transistor UT2 that are connected in series. At least one of the lower erase control transistor LT1 and the upper erase control transistor UT2 may be used for an erasure operation of deleting data stored in the memory cell transistors MCT using a gate induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection wires 1115 that extend from the first structure 1100F to the second structure 1100S. The bit lines BL may be electrically connected to the page buffer 1120 through second connection wires 1125 that extend from the first structure 1100F to the second structure 1100S.

In the first structure 1100F, the decoder circuit 1110 and the page buffer 1120 may be configured to perform a control operation on at least one selection memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 that extends from the first structure 1100F to the second structure 1100S.

Although not shown in the drawings, the first structure 1100F may include a voltage generator (not shown). The voltage generator may generate a program voltage, a read voltage, a pass voltage, and a verification voltage required for the operation of the memory cell strings CSTR. Here, the program voltage may be a relatively high voltage (e.g., 20 volts (V) to 40 V) compared to the read voltage, the pass voltage, and the verification voltage.

The first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as the program voltage applied to the word lines WL in a program operation. The page buffer 1120 may also include high-voltage transistors capable of withstanding high voltages.

The controller 1200 may include a processor 1210, a NAND controller 1220, and a host interface 1230. The electronic system 1000 may include a plurality of semiconductor devices 1100, and in this case, the controller 1200 may control the plurality of semiconductor devices 1100.

The processor 1210 may be configured to control the overall operation of the electronic system 1000 including the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. Through the NAND interface 1221, a control command to control the semiconductor device 1100, data to be written to the memory cell transistors MCT of the semiconductor device 1100, and/or data to be read from the memory cell transistors MCT of the semiconductor device 1100 may be transmitted. The host interface 1230 may provide a communication function between the electronic system 1000 and an external host. When a control command is received through the host interface 1230 from an external host, the processor 1210 may control the semiconductor device 1100 in response to the control command.

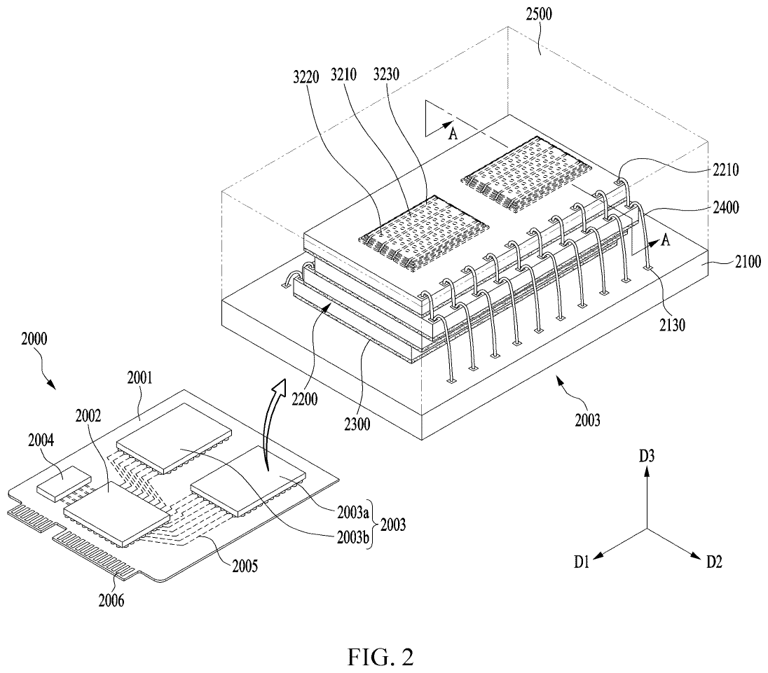

FIG. 2 is a perspective view schematically illustrating an electronic system including a semiconductor device according to at least one of the disclosure.

Referring to FIG. 2, an electronic system 2000 may include a main substrate 2001, a controller 2002 mounted on the main substrate 2001, one or more semiconductor packages 2003, and a dynamic random-access memory (DRAM) 2004. The semiconductor packages 2003 and the DRAM 2004 may be connected to the controller 2002 through wiring patterns 2005 formed on the main substrate 2001.

The main substrate 2001 may include a connector 2006 including a plurality of pins that are coupled to an external host. The number and arrangement of the plurality of pins on the connector 2006 may vary based on a communication interface between the electronic system 2000 and the external host. The electronic system 2000 may communicate with the external host according to any one of the interfaces, for example, Universal Serial Bus (USB), Peripheral Component Interconnect Express (PCI-Express), Serial Advanced Technology Attachment (SATA), and M-PHY for Universal Flash Storage (UFS). The electronic system 2000 may operate with the power supplied through the connector 2006 from the external host. The electronic system 2000 may further include a power management integrated circuit (PMIC) to distribute the power supplied from the external host to the controller 2002 and the semiconductor packages 2003.

The controller 2002 may be configured to write data to the semiconductor packages 2003 and/or to read data from the semiconductor packages 2003, thereby increasing an operating speed of the electronic system 2000.

The DRAM 2004 may be a buffer memory to reduce the speed difference between the external host and the semiconductor packages 2003 that serve as data storage spaces. The DRAM 2004 included in the electronic system 2000 may operate as a kind of cache memory, and may provide a space for temporary data storage in a control operation on the semiconductor packages 2003. When the DRAM 2004 is included in the electronic system 2000, the controller 2002 may include not only a NAND controller for controlling the semiconductor packages 2003, but a DRAM controller for controlling the DRAM 2004.

The semiconductor packages 2003 may include first and second semiconductor packages 2003a and 2003b that are spaced apart from each other. The first and second semiconductor packages 2003a and 2003b may each be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, a connection structure 2400 that electrically connects the semiconductor chips 2200 to the package substrate 2100, and a molding layer 2500 that lies on the package substrate 2100 and covers the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 1. Each of the semiconductor chips 2200 may include stacked structures 3210, channel structures 3220, and separation structures 3230. Each of the semiconductor chips 2200 may include a semiconductor device according to at least one described below.

The connection structure 2400 may be a bonding wire that electrically connects the input/output pad 2210 and the upper pads 2130. In each of the first and second semiconductor packages 2003a and 2003b, the semiconductor chips 2200 may be electrically connected to each other in a bonding wire manner, and may be electrically connected to the upper pads 2130 of the package substrate 2100. In each of the first and second semiconductor packages 2003a and 2003b, the semiconductor chips 2200 may be electrically connected to each other through connection structures including through-silicon vias (TSVs) instead of the connection structure 2400 based on the bonding wire manner. The controller 2002 and the semiconductor chips 2200 may be included in a single package. The controller 2002 and the semiconductor chips 2200 may be disposed on a separate interposer substrate other than the main substrate 2001, and the controller 2002 and the semiconductor chips 2200 may be connected to each other through wires formed on the interposer substrate.

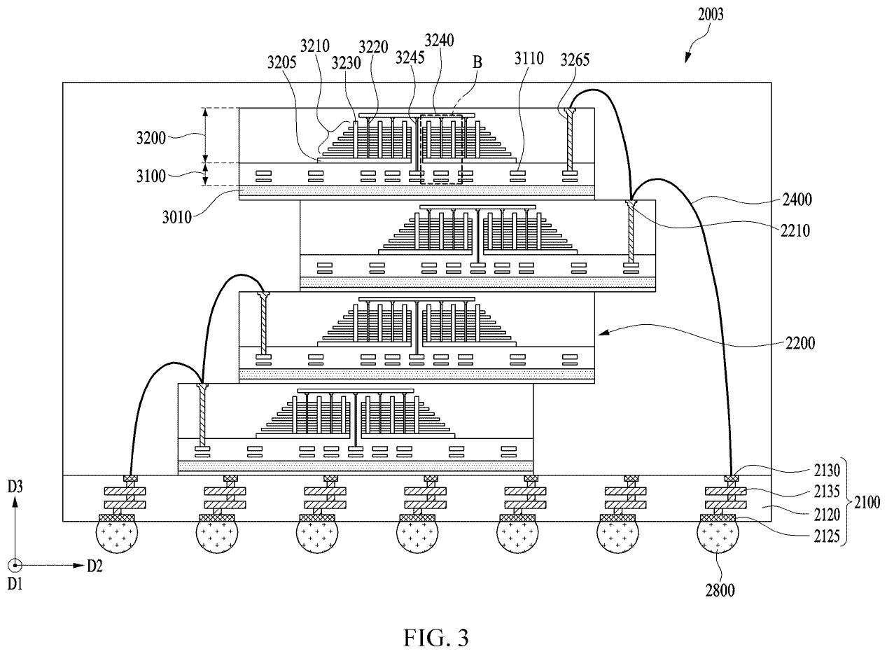

FIG. 3 is a cross-sectional view schematically illustrating a semiconductor package according to at least one. FIG. 3 depicts at least one of the semiconductor package of FIG. 2, and conceptually shows an area of the semiconductor package of FIG. 2, taken along line A-A.

Referring to FIGS. 2 and 3, in the semiconductor package 2003, the package substrate 2100 may be a printed circuit board. The package substrate 2100 may include a package substrate body portion 2120, upper pads 2130 disposed on an upper surface of the package substrate body portion 2120, lower pads 2125 disposed on or exposed through a lower surface of the package substrate body portion 2120, and inner wires 2135 electrically connecting the upper pads 2130 and the lower pads 2125 in the package substrate body portion 2120. The upper pads 2130 may be electrically connected to the connection structures 2400. The lower pads 2125 may be connected to the wiring patterns 2005 of the main substrate 2001 of the electronic system 2000 as shown in FIG. 2 through conductive connection portions 2800.

Each of the semiconductor chips 2200 may include a semiconductor substrate 3010, and a first structure 3100 and a second structure 3200 sequentially stacked on the semiconductor substrate 3010. The first structure 3100 may include a peripheral circuit area including peripheral wires 3110. The second structure 3200 may include a source structure 3205, a stacked structure 3210 on the source structure 3205, channel structures 3220 and separation structures 3230 that penetrate the stacked structure 3210, bit lines 3240 electrically connected to the channel structures 3220, and cell contact plugs (not shown) electrically connected to word lines (e.g., WL of FIG. 1) of the stacked structure 3210.

Each of the semiconductor chips 2200 may include a through wire 3245 that is electrically connected to the peripheral wires 3110 of the first structure 3100 and extends into the second structure 3200. The through wire 3245 may be disposed outside the stacked structure 3210 and may be disposed to penetrate the stacked structure 3210. Each of the semiconductor chips 2200 may further include an input/output connection wire 3265 that is electrically connected to the peripheral wires 3110 of the first structure 3100 and extends into the second structure 3200 and the input/output pad 2210 that is electrically connected to the input/output connection wire 3265.

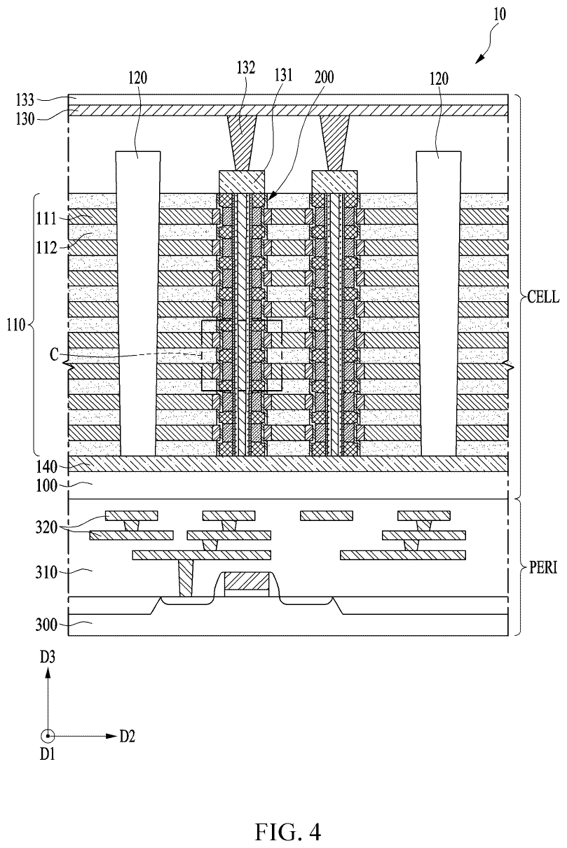

FIG. 4 is a cross-sectional view of a cell array area of a semiconductor device according to at least one. FIG. 4 is, for example, an enlarged view of an area B of FIG. 3.

Referring to FIG. 4, a semiconductor device 10 may include a memory cell structure CELL (e.g., the second structure 3200 of FIG. 3) and a peripheral circuit structure PERI (e.g., the first structure 3100 of FIG. 3).

The memory cell structure CELL may include a cell substrate 100, a stacked structure 110, a channel structure 200, a separation structure 120, a bit line 130, and a lower channel contact layer 140.

The cell substrate 100 may include, for example, a substrate including an elemental and/or compound substrate, such as a silicon substrate, a germanium substrate, or a silicon-germanium substrate. Additionally, the cell substrate 100 may include, for example, a silicon on insulator (SOI) substrate or a germanium on insulator (GOI) substrate. However, these are examples, and the type of the cell substrate 100 is not limited thereto.

The stacked structure 110 (e.g., 3210 of FIG. 3) may be positioned on the cell substrate 100. The stacked structure 110 may include a plurality of gate electrodes 111 and a plurality of interlayer insulating layers 112 that are alternately stacked along a vertical direction D3. The plurality of gate electrodes 111 and the plurality of interlayer insulating layers 112 may extend along a horizontal direction (e.g., D1 and/or D2).

The gate electrode 111 may include an electrically conductive material. For example, the gate electrode 111 may include at least one of a doped semiconductor (e.g., doped silicon), a conductive metal (e.g., tungsten, copper, molybdenum, and/or aluminum), a conductive metal nitride (e.g., titanium nitride and/or tantalum nitride), and/or a transition metal (e.g. titanium, ruthenium, and/or tantalum). However, these are merely examples, and the material of the gate electrode 111 is not limited thereto. For example, the gate electrode 111 may be used as the word line WL, the gate upper lines UL1 and UL2, and/or the gate lower lines LL1 and LL2 described above with reference to FIG. 1.

Each of the plurality of interlayer insulating layers 112 may be positioned between adjacent two gate electrodes 111. The interlayer insulating layers 112 may include an electrically insulating material. The interlayer insulating layers 112 may include, for example, at least one of silicon oxide, silicon nitride, or silicon oxynitride. However, these are merely examples, and the material of the interlayer insulating layer 112 is not limited thereto.

The separation structure 120 (e.g., 3230 in FIG. 3) may penetrate the stacked structure 110 in the vertical direction D3 and may extend in a horizontal direction (e.g., D1). The separation structure 120 may separate the stacked structure 110 into each area. The separation structure 120 may include an electrically insulating material. The separation structure 120 may include, for example, at least one of silicon oxide, silicon nitride, or silicon oxynitride. However, this is merely an example, and the material of the separation structure 120 is not limited thereto.

The channel structure 200 (e.g., 3220 of FIG. 3) may penetrate the stacked structure 110 in the vertical direction D3. For example, in at least one embodiment, the channel structure 200 may have a form of a pillar or column. The number of channel structures 200 may be more than one. The plurality of channel structures 200 may be arranged in a designated pattern. For example, the plurality of channel structures 200 may be arranged to form a grid pattern or arranged in a zigzag pattern.

The channel structure 200 may be electrically connected to the bit line 130 and/or the lower channel contact layer 140. For example, an upper end of the channel structure 200 may be electrically connected to the bit line 130. For example, the channel structure 200 may be electrically connected to the bit line 130 through a channel contact pad 131 and a bit line contact structure 132. An upper insulating layer 133 may be positioned on an upper surface of the bit line 130. For example, a lower end of the channel structure 200 may be electrically connected to the lower channel contact layer 140. The lower channel contact layer 140 may be a portion electrically connected to a source structure (e.g., 3205 of FIG. 3) or a portion that substantially functions as a source structure (e.g., 3205 of FIG. 3). However, this is merely an example, and the structure in which the channel structure 200 is connected to the bit line 130 and/or the source structure (e.g., 3205 of FIG. 3) is not limited thereto. In addition, the structures of the bit line 130, the channel contact pad 131, the bit line contact structure 132, and/or the lower channel contact layer 140 shown in the drawing are merely examples, and the structure of each component is not limited thereto.

The peripheral circuit structure PERI may include a peripheral circuit board 300, a wiring insulating layer 310, and a wiring structure 320.

The peripheral circuit board 300 may be positioned below the cell substrate 100. For example, an upper surface of the peripheral circuit board 300 may face a lower surface of the cell substrate 100. The peripheral circuit board 300 may include, for example, a substrate including a semiconductor such as a silicon substrate, a germanium substrate, or a silicon-germanium substrate. In at least some examples, the peripheral circuit board 300 may include, for example, a SOI substrate or a GOI substrate. However, this is merely an example, and the type of the peripheral circuit board 300 is not limited thereto. The wiring insulating layer 310 and the wiring structure 320 may be formed on the peripheral circuit board 300. A decoder (e.g., 1110 of FIG. 1), a page buffer (e.g., 1120 of FIG. 1), and/or a logic circuit (e.g., 1130 of FIG. 1) for controlling the operations of the semiconductor device 10 may be formed on the peripheral circuit board 300. However, this is merely an example, and the structure of the peripheral circuit structure PERI is not limited thereto.

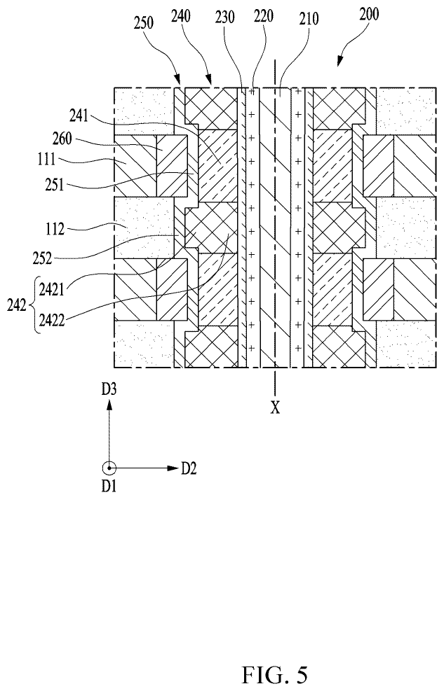

FIG. 5 is an enlarged cross-sectional view illustrating a channel structure of a semiconductor device according to at least one. For example, FIG. 5 is an enlarged view of an area C of FIG. 4.

Referring to FIG. 5, the channel structure 200 may include a core insulating layer 210, a channel poly layer 220, a channel insulating layer 230, a crystalline layer 240, an electron trap layer 250, and a gate insulating layer 260. Hereinafter, when describing each component, an inward direction refers to a horizontal direction from the outside toward a center X of the channel structure 200, and an outward direction refers to a horizontal direction from the center X of the channel structure 200 toward the outside, unless otherwise noted.

The core insulating layer 210 may be positioned at the center of the channel structure 200. The core insulating layer 210 may include an electrically insulating material. The core insulating layer 210 may be formed along the vertical direction D3. The core insulating layer 210 may be formed substantially in a form of a pillar. For example, the core insulating layer 210 may include at least one of silicon oxide, silicon nitride, or silicon oxynitride. However, this is merely an example, and the material of the core insulating layer 210 is not limited thereto.

The channel poly layer 220 may be positioned outside the core insulating layer 210. The channel poly layer 220 may be positioned to surround an outer surface of the core insulating layer 210. The channel poly layer 220 may be formed along the vertical direction D3. The channel poly layer 220 may be a portion electrically connected to a bit line (e.g., 130 of FIG. 4) and a lower channel contact layer (e.g., 140 of FIG. 4). For example, the channel poly layer 220 may include a semiconductor material such as polysilicon. However, this is merely an example, and the material of the channel poly layer 220 is not limited thereto.

The channel insulating layer 230 may be positioned outside the channel poly layer 220. The channel insulating layer 230 may be positioned to surround an outer surface of the channel poly layer 220. The channel insulating layer 230 may be formed along the vertical direction D3. The channel insulating layer 230 may include an electrically insulating material. For example, the channel insulating layer 230 may include at least one of silicon oxide, silicon nitride, silicon oxynitride and/or a high-k material having a high dielectric constant. The high-k material may refer to a material having a dielectric constant of 4 Farads/meter (F/m) or more. For example, the channel insulating layer 230 may include at least one nitride, oxide, or oxynitride selected from a group consisting of silicon (Si), lanthanum (La), aluminum (Al), hafnium (Hf), zirconium (Zr), and titanium (Ti), and specifically, may include at least one of SiN, SiON, LaO, AlN, AlON, HIN, HfON, ZrN, ZrON, TiN, TiON, and/or a combination thereof. For example, the channel insulating layer 230 may be manufactured by combining different materials in a multilayer stacked form. However, this is merely an example, and the material of the channel insulating layer 230 is not limited thereto.

The crystalline layer 240 may be positioned outside the channel insulating layer 230 and the channel poly layer 220. The crystalline layer 240 may be positioned to surround an outer surface of the channel insulating layer 230. The channel insulating layer 230 may be positioned between the channel poly layer 220 and the crystalline layer 240. The crystalline layer 240 may be formed along the vertical direction D3. The crystalline layer 240 may include a material having a polymorphic crystal. For example, the crystalline layer 240 may be configured to have an orthorhombic crystal structure and a monoclinic crystal structure. For example, the crystalline layer 240 may include hafnium (Hf) and/or zirconium (Zr). For example, the crystalline layer 240 may include Hf₁₋ₓZrₓO₂ (0≤x≤1), and specifically may be HfO2 or ZrO2. In addition, the crystalline layer 240 may further include a dopant doped into the Hf₁₋ₓZrₓO₂ (0≤x≤1), and the dopant may contain at least one of aluminum (Al), carbon (C), nitrogen (N), gadolinium (Gd), yttrium (Y), tantalum (Ta), lanthanum (La), or silicon (Si), and/or a combination thereof. For example, the crystalline layer 240 may exist in a form of a solid solution or a superlattice. For example, the dopant may exist in a dispersed structure in a thin film of the crystalline layer 240 or may exist to be agglomerated in a form of a localized layer by an atomic layer deposition (ALD) process. However, this is merely an example, and a crystal form and/or the type of material of the crystalline layer 240 are not limited thereto.

The crystalline layer 240 may include a plurality of ferroelectric layers 241 and a plurality of paraelectric layers 242. The plurality of ferroelectric layers 241 and the plurality of paraelectric layers 242 may be positioned alternately along the vertical direction D3. The plurality of ferroelectric layers 241 may be positioned to be spaced apart from each other along the vertical direction D3. The plurality of ferroelectric layers 241 may be positioned at a height substantially corresponding to the plurality of gate electrodes 111. For example, each of the ferroelectric layers 241 may be positioned to overlap each of the gate electrodes 111 in at least one horizontal direction (D1 and/or D2). The plurality of paraelectric layers 242 may be positioned to be spaced apart from each other in the vertical direction D3. The plurality of paraelectric layers 242 may be positioned at a height substantially corresponding to the plurality of interlayer insulating layers 112. For example, each of the paraelectric layers 242 may be positioned to overlap each of the interlayer insulating layers 112 in the horizontal direction (D1 and/or D2). The ferroelectric layer 241 and the paraelectric layer 242 may have a substantially annular shape. The ferroelectric layer 241 may be a portion having ferroelectric properties, and the paraelectric layer 242 may be a portion having paraelectric properties. The plurality of ferroelectric layers 241 and the plurality of paraelectric layers 242 may be configured to have different crystal structures while containing the same material. For example, the ferroelectric layer 241 may have an orthorhombic crystal structure, and the paraelectric layer 242 may have a monoclinic crystal structure. However, this is merely an example, and the crystal structures of the ferroelectric layer 241 and the paraelectric layer 242 are not limited thereto.

The electron trap layer 250 may be positioned outside the crystalline layer 240. The electron trap layer 250 may be positioned to surround an outer surface of the crystalline layer 240. The electron trap layer 250 may be formed along the vertical direction D3. The electron trap layer 250 may be a layer in which electrons are trapped and stored. For example, the electron trap layer 250 may include at least one or a combination of oxide, nitride or oxynitride of silicon (Si) or hafnium (Hf), and may include, for example, at least one of SiN, SiON, or HfO2, and/or a combination thereof. In addition, the electron trap layer 250 may further include a dopant doped into at least one material of the oxide, nitride, or oxynitride of the silicon (Si) or hafnium (Hf), and may further include a dopant doped into SiN or SiON. In these cases, for example, the dopant may contain at least one of hafnium (Hf), zirconium (Zr), aluminum (Al), carbon (C), nitrogen (N), gadolinium (Gd), yttrium (Y), titanium (Ti), lanthanum (La), or tantalum (Ta), and/or a combination thereof. For example, the electron trap layer 250 may be manufactured by combining different materials in a multilayer stacked form. However, this is merely an example, and the material of the electron trap layer 250 is not limited thereto.

A plurality of gate insulating layers 260 may be positioned to be spaced apart from each other in the vertical direction D3. The plurality of gate insulating layers 260 may be positioned at a height substantially corresponding to the plurality of gate electrodes 111. For example, each of the gate insulating layers 260 may be positioned to overlap each of the gate electrodes 111 in the horizontal direction (D1 and/or D2). The plurality of gate insulating layers 260 may be positioned between the electron trap layer 250 and the plurality of gate electrodes 111. For example, each of the gate insulating layers 260 may have an inner side surface coming into contact with the electron trap layer 250 and an outer side surface coming into contact with each of the gate electrodes 111. The gate insulating layer 260 may have a substantially annular shape. A thickness of the gate insulating layer 260 in the vertical direction may be substantially the same as a thickness of the gate electrode 111. The gate insulating layer 260 may be a layer through which electrons tunnel. For example, electrons of the gate electrode 111 may tunnel through the gate insulating layer 260 to be trapped in at least a portion (e.g., a first electron trap layer portion 251) of the electron trap layer 250. For example, the gate insulating layer 260 may include at least one of SiO2, SiN, or SiON, or a combination thereof. In addition, the gate insulating layer 260 may further include a dopant doped into the material described above, and the dopant may contain at least one of hafnium (Hf), zirconium (Zr), aluminum (Al), carbon (C), nitrogen (N), gadolinium (Gd), yttrium (Y), titanium (Ti), lanthanum (La), or tantalum (Ta), or a combination thereof. For example, the gate insulating layer 260 may be manufactured by combining different materials in a multilayer stacked form. However, this is merely an example, and the material of the gate insulating layer 260 is not limited thereto.

Based on each channel structure 200, an inner end portion of the plurality of interlayer insulating layers 112 may protrude further inward toward the center X of the channel structure 200 than an inner end portion of the plurality of gate electrodes 111. For example, a radius from the center X of the channel structure 200 to the inner end portion of the plurality of interlayer insulating layers 112 may be smaller than a radius from the center X of the channel structure 200 to the inner end portion of the plurality of gate electrodes 111. The inner end portion of the plurality of gate insulating layers 260 may be positioned further inward than the inner end portion of the plurality of interlayer insulating layers 112. An outer end portion of the plurality of gate insulating layers 260 may be positioned further outward than the inner end portion of the plurality of interlayer insulating layers 112. For example, the radius from the center X of the channel structure 200 to the inner end portion of the plurality of interlayer insulating layers 112 may be greater than a radius from the center X of the channel structure 200 to the inner end portion of the plurality of gate insulating layers 260, and may be smaller than a radius from the center X of the channel structure 200 to the outer end portion of the plurality of gate insulating layers 260.

The electron trap layer 250 may include a plurality of first electron trap layer portions 251 and a plurality of second electron trap layer portions 252. The plurality of first electron trap layer portions 251 and the plurality of second electron trap layer portions 252 may be substantially alternately positioned along the vertical direction D3. The plurality of first electron trap layer portions 251 may be positioned to be spaced apart from each other in the vertical direction D3. The plurality of first electron trap layer portions 251 may be positioned at a height substantially corresponding to the plurality of gate electrodes 111. For example, each of the first electron trap layer portions 251 may be positioned to overlap each of the gate electrodes 111 in the horizontal direction (D1 and/or D2). The plurality of second electron trap layer portions 252 may be positioned to be spaced apart from each other in the vertical direction D3. The plurality of second electron trap layer portions 252 may be positioned at a height substantially corresponding to the plurality of interlayer insulating layers 112. For example, each of the second electron trap layer portions 252 may be positioned to overlap each of the interlayer insulating layers 112 in the horizontal direction (D1 and/or D2). The first electron trap layer portion 251 and the second electron trap layer portion 252 may be formed substantially in an annular shape.

Based on each channel structure 200, the plurality of first electron trap layer portions 251 may be positioned further inward than the plurality of second electron trap layer portions 252. For example, a radius from the center X of the channel structure 200 to an inner end portion of the plurality of first electron trap layer portions 251 may be smaller than a radius from the center X of the channel structure 200 to an inner end portion of the plurality of second electron trap layer portions 252. The electron trap layer 250 may form an unevenness in the horizontal direction (D1 and/or D2) along the vertical direction D3 as the plurality of first electron trap layer portions 251 and the plurality of second electron trap layer portions 252 are alternately positioned along the vertical direction D3.

Based on each channel structure 200, an outer end portion of the plurality of paraelectric layers 242 may protrude further outward than an outer end portion of the plurality of ferroelectric layers 241. For example, a radius from the center X of the channel structure 200 to the outer end portion of the plurality of paraelectric layers 242 may be greater than a radius from the center X of the channel structure 200 to the outer end portion of the plurality of ferroelectric layers 241. For example, a difference between the radius from the center X of the channel structure 200 to the outer end portion of the plurality of paraelectric layers 242 and the radius from the center X of the channel structure 200 to the outer end portion of the plurality of ferroelectric layers 241 may be about 30 Å or less and/or about 20 Å or less. For example, a width of a first paraelectric layer portion 2421 to be described below may be about 30 Å or less and/or about 20 Å or less.

The inner end portion of the plurality of paraelectric layers 242 and the inner end portion of the plurality of ferroelectric layers 241 may be aligned in the vertical direction D3 along the channel insulating layer 230. For example, a radius from the center X of the channel structure 200 to the inner end portion of the plurality of paraelectric layers 242 may be substantially the same as a radius from the center X of the channel structure 200 to the inner end portion of the plurality of ferroelectric layers 241. A length of each of the paraelectric layers 242 protruding radially from the channel insulating layer 230 may be longer than a length of each of the ferroelectric layers 241 protruding radially from the channel insulating layer 230. For example, the length of each of the ferroelectric layers 241 protruding radially from the channel insulating layer 230 may be about 3 Å or more and about 100 Å or less.

The paraelectric layer 242 may include the first paraelectric layer portion 2421 and a second paraelectric layer portion 2422. The first paraelectric layer portion 2421 may be positioned inside the second electron trap layer portion 252. For example, the first paraelectric layer portion 2421 may be formed on an inner side surface of the second electron trap layer portion 252. The first paraelectric layer portion 2421 may be positioned between two first electron trap layer portions 251 positioned adjacent to each other in the vertical direction D3. For example, the first paraelectric layer portion 2421 may be positioned in a recessed portion of the unevenness formed by the electron trap layer 250. The second paraelectric layer portion 2422 may extend inward from the first paraelectric layer portion 2421. The second paraelectric layer portion 2422 may be positioned between the first paraelectric layer portion 2421 and the channel insulating layer 230. For example, the second paraelectric layer portion 2422 may have a thickness greater than a thickness of the first paraelectric layer portion 2421.

A thickness of a thickest portion of the paraelectric layer 242 may be smaller than a thickness of the interlayer insulating layer 112. For example, the thickness of the second paraelectric layer portion 2422 may be smaller than the thickness of the interlayer insulating layer 112. A thickness of the ferroelectric layer 241 may be greater than a thickness of the gate electrode 111. However, this is merely an example, and the shape of the paraelectric layer 242 and/or the ferroelectric layer 241 is not limited thereto. For example, the thickness of the second paraelectric layer portion 2422 may be greater than the thickness of the interlayer insulating layer 112, and the thickness of the ferroelectric layer 241 may be smaller than the thickness of the gate electrode 111.

The ferroelectric layer 241 may be configured to have various polarization states depending on a voltage applied between the gate electrode 111 and the channel poly layer 220. Specifically, remanent polarization may be generated in the ferroelectric layer 241 by a voltage applied between the gate electrode 111 and the channel poly layer 220. For example, a magnitude of the remanent polarization generated in the ferroelectric layer 241 may be determined by the polarization-voltage (PV) hysteresis characteristics of the ferroelectric layer 241. The generated remanent polarization may be stored in the ferroelectric layer 241, and signal information may be stored in a non-volatile manner by the stored remanent polarization. Through this, the ferroelectric layer 241 may function as a non-volatile memory layer. The channel insulating layer 230 and/or the electron trap layer 250 positioned on both sides of the ferroelectric layer 241 may stabilize the remanent polarization of the ferroelectric layer 241. For example, at least a portion of the channel insulating layer 230 and/or the electron trap layer 250 positioned adjacent to the ferroelectric layer 241 may be polarized in a direction that conforms to a remanent polarization direction of the ferroelectric layer 241, thereby stabilizing the remanent polarization state of the ferroelectric layer 241.

According to the channel structure 200 according to at least one, the ferroelectric layer 241 may be formed in an area corresponding to the gate electrode 111, and the paraelectric layer 242 may be formed in an area corresponding to the interlayer insulating layer 112. According to such a structure, when a voltage is applied to the gate electrode 111, remanent polarization may be generated only in the ferroelectric layer 241, and no (or negligible) remanent polarization may be generated in the paraelectric layer 242. Since no remanent polarization is generated in the paraelectric layer 242, a phenomenon of random polarization being generated in the crystalline layer 240 may be prevented or reduced, and thus the distribution of a threshold voltage may be improved. Since no remanent polarization is generated in the paraelectric layer 242, a phenomenon of electrons being injected from the channel insulating layer 230 to the paraelectric layer 242 may be prevented or reduced, and thus a magnitude of a cell current may be increased. Since no remanent polarization is generated in the paraelectric layer 242, a phenomenon of electrons trapped in the first electron trap layer portion 251 spreading to the second electron trap layer portion 252 may be prevented or reduced, and thus, the electron retention ability of the electron trap layer 250 may be improved.

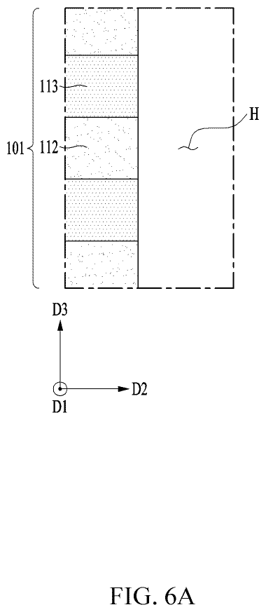

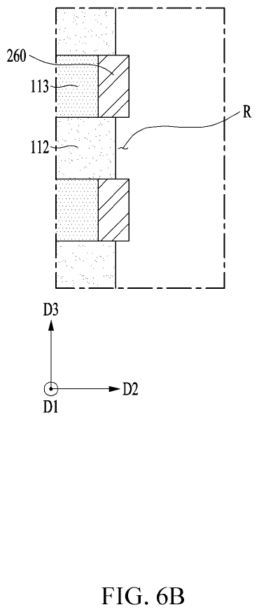

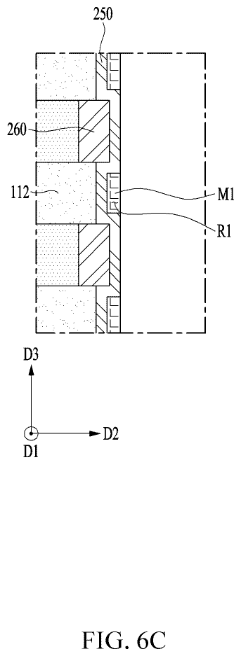

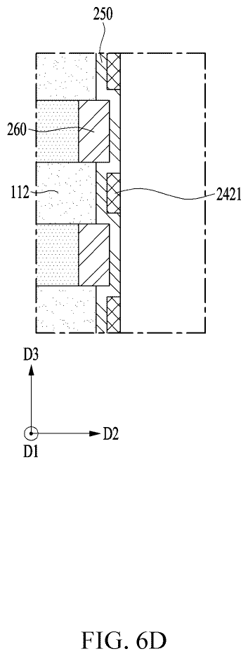

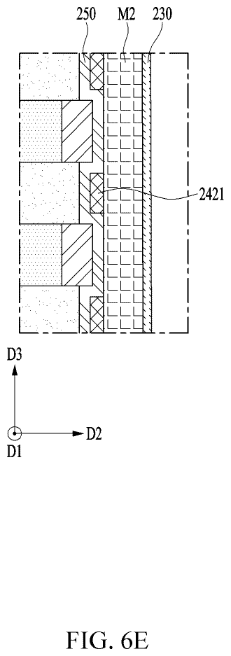

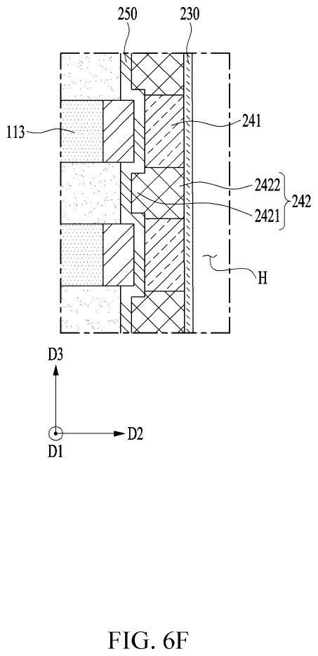

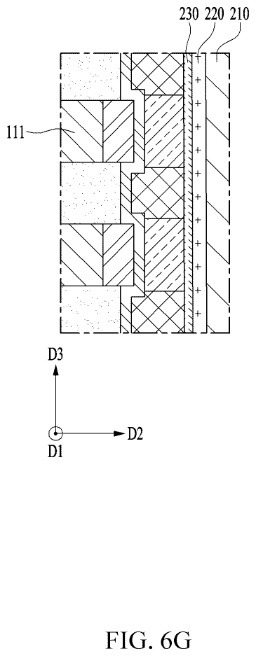

FIGS. 6A to 6G are partial cross-sectional views illustrating a process of manufacturing a channel structure according to at least one. Hereinafter, a method of manufacturing a channel structure (e.g., the channel structure 200 of FIG. 5) according to at least one will be described with reference to FIGS. 6A to 6G. Hereinafter, when describing each component, an inward direction refers to a horizontal direction (e.g., D2) from the outside toward a center of a channel hole H, unless otherwise noted.

Referring to FIG. 6A, a mold structure 101 may be stacked on a substrate. The mold structure 101 may include a plurality of sacrificial insulating layers 113 and the plurality of interlayer insulating layers 112 that are alternately stacked. A channel hole H may be formed in the mold structure 101 along the vertical direction D3 using an etching process.

Referring to FIG. 6B, a portion of an inner end portion of the interlayer insulating layer 112 may be removed by an etching process to form a recess R. The etching process forming the recess R may be the same as and/or a different process from the channel hole H. The gate insulating layer 260 may be formed on an inner end portion of the sacrificial insulating layer 113. For example, the gate insulating layer 260 may be formed as a portion of the inner end portion of the sacrificial insulating layer 113 is oxidized. The inner end portion of the interlayer insulating layer 112 and the inner end portion of the gate insulating layer 260 may form an unevenness along the vertical direction D3.

Referring to FIG. 6C, the electron trap layer 250 may be deposited on an inner side surface of the interlayer insulating layer 112 and an inner side surface of the gate insulating layer 260. The electron trap layer 250 may be formed to have an unevenness corresponding to the unevenness formed by the interlayer insulating layer 112 and the gate insulating layer 260. A width of a recessed portion R1 (e.g., in the horizontal direction D2) of the unevenness formed by the electron trap layer 250 may be about 30 Å or less and/or about 20 Å or less. Then, an amorphous dielectric material M1 may be primarily deposited on an inner side surface of the electron trap layer 250. For example, the amorphous dielectric material M1 may be a material containing hafnium (Hf) and/or zirconium (Zr). For example, the amorphous dielectric material M1 may include Hf₁₋ₓZrₓO₂ (0≤x≤1), and specifically, may be HfO2 or ZrO2. In addition, the amorphous dielectric material M1 may further include a dopant doped into the Hf₁₋ₓZrₓO₂ (0≤x≤1), and the dopant may contain at least one of aluminum (Al), carbon (C), nitrogen (N), gadolinium (Gd), yttrium (Y), tantalum (Ta), lanthanum (La), silicon (Si), and/or a combination thereof. Afterwards, as shown in FIG. 6C, a trimming process may be performed so that the amorphous dielectric material M1 remains only in the recessed portion R1 of the unevenness formed by the electron trap layer 250.

Then, a primary annealing process may be performed to crystallize the amorphous dielectric material M1. The primary annealing process may be performed under conditions for crystallizing the amorphous dielectric material M1 to have a crystal structure having paraelectricity. By the primary annealing process, the amorphous dielectric material M1 of FIG. 6C may be crystallized to have paraelectricity, thereby forming the first paraelectric layer portion 2421 as shown in FIG. 6D. For example, when a deposition thickness of the amorphous dielectric material M1 is about 30 Å or less or about 20 Å or less and an annealing temperature is between 200 degrees Celsius and 500 degrees Celsius, the amorphous dielectric material M1 may be crystallized into a monoclinic crystal structure having paraelectricity.

Next, as shown in FIG. 6E, an amorphous dielectric material M2 may be secondarily deposited on inner side surfaces of the electron trap layer 250 and the first paraelectric layer portion 2421. The amorphous dielectric material M2 may be substantially the same material as the amorphous dielectric material M1 of FIG. 6C. The channel insulating layer 230 may be deposited on the inner side surface of the amorphous dielectric material M2.

Next, a secondary annealing process may be performed so that the amorphous dielectric material M2 is crystallized. At this time, a portion of the amorphous dielectric material M2 in direct contact with the first paraelectric layer portion 2421 may be grown to have a crystal structure (e.g., a monoclinic crystal structure) having the same paraelectricity as the first paraelectric layer portion 2421 through epitaxial growth. For example, the first paraelectric layer portion 2421 may act a seed layer on which a crystalline grain propagates from, thereby the crystalline structure of the first paraelectric layer portion 2421 may induce a corresponding crystalline structure in the paraelectric crystal structure growing in amorphous dielectric material M2. As such, in at least some embodiments, the crystalline structure of the paraelectric crystal structure growing in amorphous dielectric material M2 may have the same crystalline structure type (e.g., a monoclinic crystal structure) as the paraelectric layer portion 2421. As shown in FIG. 6F, a portion of the amorphous dielectric material M2 in direct contact with the first paraelectric layer portion 2421 may be crystallized to have paraelectricity, thereby forming the second paraelectric layer portion 2422. The remaining portion of the amorphous dielectric material M2 may be crystallized to have ferroelectricity, thereby forming the ferroelectric layer 241 as shown in FIG. 6F. For example, the ferroelectric layer 241 may have an orthorhombic crystal structure. The secondary appealing process may be performed at a temperature range wherein the portion of the amorphous dielectric material M2 in direct contact with the first paraelectric layer portion 2421 may be crystallized to have paraelectricity and remaining portion of the amorphous dielectric material M2 may be crystallized to have ferroelectricity, and may be adjusted based on the material composition of the amorphous dielectric material M2. According to such a manufacturing method, the ferroelectric layer 241 and the paraelectric layer 242 may be formed to have different crystal structures while containing the same material. The ferroelectric layer 241 and the paraelectric layer 242 may have different dielectric properties that appear according to the respective crystal structures. For example, the ferroelectric layer 241 may exhibit ferroelectricity as it has an orthorhombic crystal structure, and the paraelectric layer 242 may exhibit paraelectricity as it has a monoclinic crystal structure.

Next, as shown in FIG. 6G, the channel poly layer 220 may be deposited on an inner side surface of the channel insulating layer 230. The remaining empty space of the channel hole H may be filled with the core insulating layer 210. The sacrificial insulating layer 113 of FIG. 6F may be replaced with the gate electrode 111 as shown in FIG. 6G.

Meanwhile, the method of manufacturing the channel structure described above is merely an example, and the method of manufacturing the channel structure is not limited thereto.

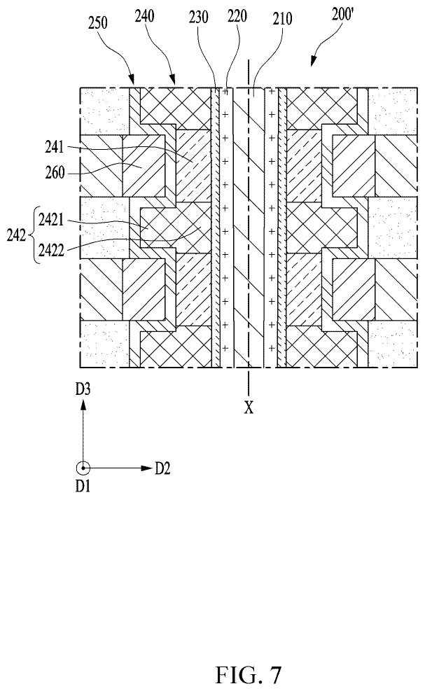

FIG. 7 is an enlarged cross-sectional view illustrating a channel structure of a semiconductor device according to at least one. FIG. 7 is an enlarged view of an area corresponding to the area C of FIG. 4 in the semiconductor device.

Referring to FIG. 7, a channel structure 200′ may include the core insulating layer 210, the channel poly layer 220, the channel insulating layer 230, the crystalline layer 240, the electron trap layer 250, and the gate insulating layer 260. In the description of at least one with reference to FIG. 7, the contents described above with reference to FIG. 5 will be applied to components common to the components described above with reference to FIG. 5 within a range not contradicting each other.

Based on each channel structure 200′, the outer end portion of the plurality of paraelectric layers 242 may protrude further outward than the outer end portion of the plurality of ferroelectric layers 241. For example, a radius from the center X of the channel structure 200′ to the outer end portion of the plurality of paraelectric layers 242 may be greater than a radius from the center X of the channel structure 200′ to the outer end portion of the plurality of ferroelectric layers 241. For example, a difference between the radius from the center X of the channel structure 200′ to the outer end portion of the plurality of paraelectric layers 242 and the radius from the center X of the channel structure 200′ to the outer end portion of the plurality of ferroelectric layers 241 may be about 100 Å or more, and about 300 Å or less or about 200 Å or less. For example, a width of the first paraelectric layer portion 2421 may be about 100 Å or more and about 300 Å or less or about 200 Å or less.

The inner end portion of the plurality of paraelectric layers 242 and the inner end portion of the plurality of ferroelectric layers 241 may be aligned in the vertical direction D3 along the channel insulating layer 230. For example, a radius from the center X of the channel structure 200′ to the inner end portion of the plurality of paraelectric layers 242 may be substantially the same as a radius from the center X of the channel structure 200′ to the inner end portion of the plurality of ferroelectric layers 241. A length of each of the paraelectric layers 242 protruding radially from the channel insulating layer 230 may be longer than a length of each of the ferroelectric layers 241 protruding radially from the channel insulating layer 230.

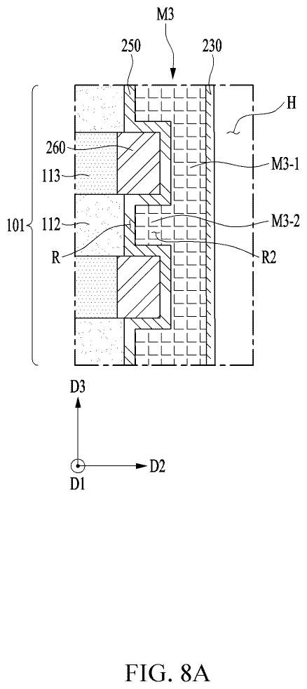

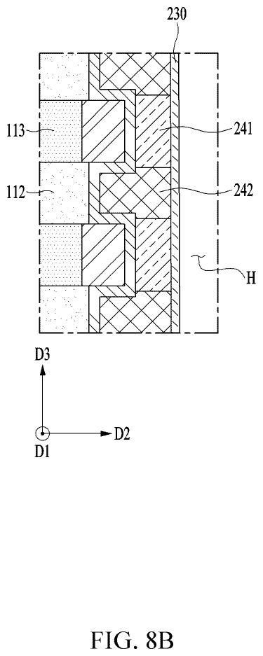

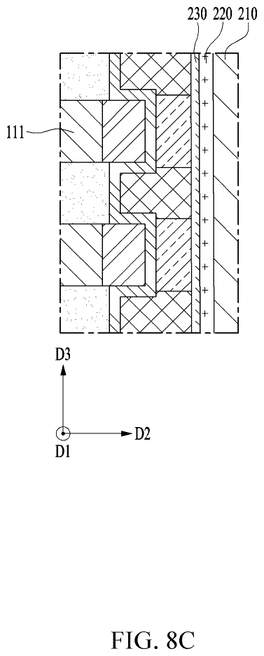

FIGS. 8A to 8C are partial cross-sectional views illustrating a process of manufacturing a channel structure according to at least one. Hereinafter, a method of manufacturing a channel structure (e.g., the channel structure 200′ of FIG. 7) according to at least one will be described with reference to FIGS. 8A to 8C. Hereinafter, when describing each component, an inward direction refers to a horizontal direction (e.g., D2) from the outside toward a center of a channel hole H, unless otherwise noted.

Referring to FIG. 8A, the mold structure 101 may be stacked on a substrate. The mold structure 101 may include the plurality of sacrificial insulating layers 113 and the plurality of interlayer insulating layers 112 that are alternately stacked. By an etching process, the channel hole H may be formed in the mold structure 101 along the vertical direction D3. A portion of an inner end portion of the interlayer insulating layer 112 may be removed by the etching process to form a recess R. The gate insulating layer 260 may be formed on an inner end portion of the sacrificial insulating layer 113. For example, the gate insulating layer 260 may be formed as a portion of the inner end portion of the sacrificial insulating layer 113 is oxidized. The inner end portion of the interlayer insulating layer 112 and the inner end portion of the gate insulating layer 260 may form an unevenness along the vertical direction D3.

Then, the electron trap layer 250 may be deposited on an inner side surface of the interlayer insulating layer 112 and an inner side surface of the gate insulating layer 260. The electron trap layer 250 may be formed to have an unevenness corresponding to the unevenness formed by the interlayer insulating layer 112 and the gate insulating layer 260. A width of a recessed portion R2 of the unevenness formed by the electron trap layer 250 may be about 100 Å or more, and about 300 Å or less or about 200 Å or less. Then, an amorphous dielectric material M3 may be deposited on the inner side surface of the electron trap layer 250. For example, the amorphous dielectric material M3 may be a material containing hafnium (Hf) and/or zirconium (Zr). For example, the amorphous dielectric material M3 may include Hf₁₋ₓZrₓO₂ (0≤x≤1), and specifically, may be HfO2 or ZrO2. In addition, the amorphous dielectric material M3 may further include a dopant doped into the Hf₁₋ₓZrₓO₂ (0≤x≤1), and the dopant may contain at least one of aluminum (Al), carbon (C), nitrogen (N), gadolinium (Gd), yttrium (Y), tantalum (Ta), lanthanum (La), or silicon (Si), or a combination thereof. Next, a trimming process for the amorphous dielectric material M3 may be performed. The channel insulating layer 230 may be deposited on an inner side surface of the amorphous dielectric material M3.

Next, as shown in FIG. 8B, an annealing process may be performed to crystallize the amorphous dielectric material M3. During the annealing process, each portion of the amorphous dielectric material M3 may be crystallized to have different crystal structures depending on a deposition thickness and/or a composition ratio. For example, based on a ratio of Zr in the amorphous dielectric material M3 being about 0.5, when a thickness of the amorphous dielectric material M3 is about 100 Å to about 200 Å, the amorphous dielectric material M3 may be crystallized to have a monoclinic crystal structure exhibiting paraelectricity, and when the thickness of the amorphous dielectric material M3 is about 300 Å or more (or about 400 Å or more), the amorphous dielectric material M3 may be crystallized to have an orthorhombic crystal structure exhibiting ferroelectricity. For example, in FIGS. 8A and 8B, a portion M3-1 positioned at a height corresponding to the sacrificial insulating layer 113 of the amorphous dielectric material M3 has a relatively thin deposition thickness, and thus, it may be crystallized to have an orthorhombic crystal structure to form the ferroelectric layer 241. For example, in FIGS. 8A and 8B, a portion M3-2 positioned at a height corresponding to the interlayer insulating layer 112 of the amorphous dielectric material M3 has a relatively thick deposition thickness, and thus, it may be crystallized to have a monoclinic crystal structure to form the paraelectric layer 242. According to such a manufacturing method, the ferroelectric layer 241 and the paraelectric layer 242 may be formed to have different crystal structures while containing the same material. The ferroelectric layer 241 and the paraelectric layer 242 may have different dielectric properties that appear according to the respective crystal structures. For example, the ferroelectric layer 241 may exhibit ferroelectricity as it has an orthorhombic crystal structure, and the paraelectric layer 242 may exhibit paraelectricity as it has a monoclinic crystal structure.

Next, as shown in FIG. 8C, the channel poly layer 220 may be deposited on an inner side surface of the channel insulating layer 230. The remaining empty space of the channel hole H may be filled with the core insulating layer 210. The sacrificial insulating layer 113 of FIG. 8B may be replaced with the gate electrode 111 as shown in FIG. 8C.

Meanwhile, the method of manufacturing the channel structure described above is merely an example, and the method of manufacturing the channel structure is not limited thereto.

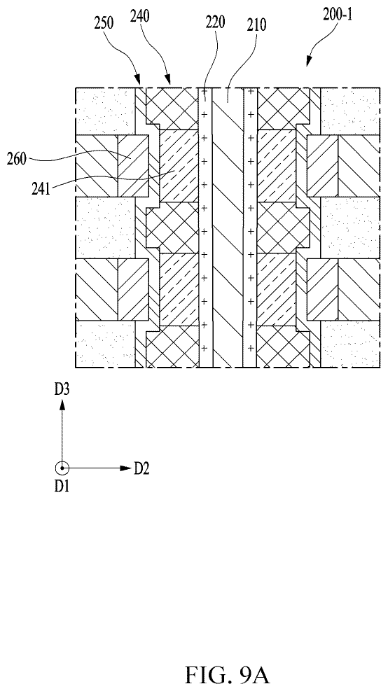

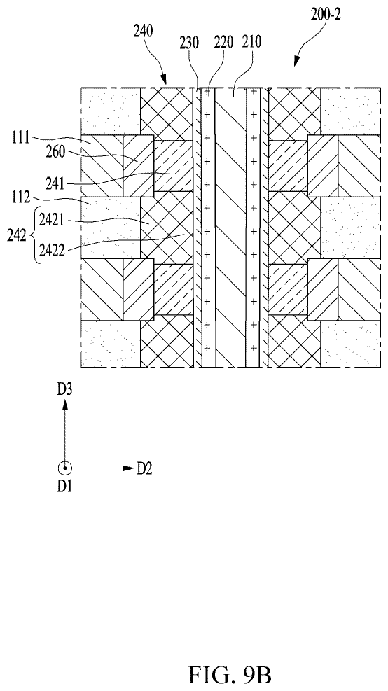

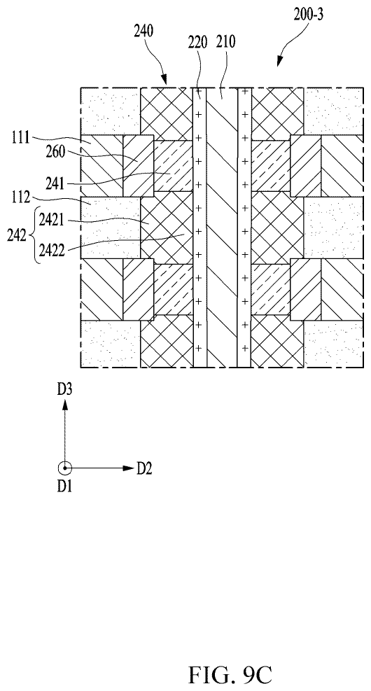

FIG. 9A is an enlarged cross-sectional view illustrating a channel structure of a semiconductor device according to at least one. FIG. 9A is an enlarged view of an area corresponding to the area C of FIG. 4 in the semiconductor device.

Referring to FIG. 9A, a channel structure 200-1 may include the core insulating layer 210, the channel poly layer 220, the crystalline layer 240, the electron trap layer 250, and the gate insulating layer 260. The channel structure 200-1 described with reference to FIG. 9A may be a structure in which the channel insulating layer 230 is omitted from the channel structure 200 and/or 200′ described with reference to FIG. 5 and/or FIG. 7. In the case of the channel structure 200-1 described with reference to FIG. 9A, the channel poly layer 220 and/or the electron trap layer 250 positioned on both sides of the ferroelectric layer 241 may stabilize the remanent polarization of the ferroelectric layer 241. For example, at least a portion of the channel poly layer 220 and/or the electron trap layer 250 positioned adjacent to the ferroelectric layer 241 may be polarized in a direction that conforms to the remanent polarization direction of the ferroelectric layer 241, thereby stabilizing the remanent polarization state of the ferroelectric layer 241. The contents described above with reference to FIG. 5 and/or FIG. 7 are applied to the remaining components of the channel structure 200-1 described above with reference to FIG. 9A within a range not contradicting each other.

FIG. 9B is an enlarged cross-sectional view illustrating a channel structure of a semiconductor device according to at least one. FIG. 9B is an enlarged view of an area corresponding to the area C of FIG. 4 in the semiconductor device.

Referring to FIG. 9B, a channel structure 200-2 may include the core insulating layer 210, the channel poly layer 220, the channel insulating layer 230, the crystalline layer 240, and the gate insulating layer 260. The channel structure 200-2 described with reference to FIG. 9B may be a structure in which the electron trap layer 250 is omitted from the channel structure 200 and/or 200′ described with reference to FIG. 5 and/or FIG. 7. The plurality of gate insulating layers 260 may be positioned between the crystalline layer 240 and the plurality of gate electrodes 111 at a height corresponding to the plurality of gate electrodes 111. In the case of the channel structure 200-2 described with reference to FIG. 9B, the channel insulating layer 230 and/or the gate insulating layer 260 positioned on both sides of the ferroelectric layer 241 may stabilize the remanent polarization of the ferroelectric layer 241. For example, at least a portion of the channel insulating layer 230 and/or the gate insulating layer 260 positioned adjacent to the ferroelectric layer 241 may be polarized in a direction that conforms to the remanent polarization direction of the ferroelectric layer 241, thereby stabilizing the remanent polarization state of the ferroelectric layer 241. For example, the gate insulating layer 260 may include a low-k material having a low dielectric constant. The low-k material may refer to a material having a dielectric constant of 4 F/m or less. However, this is merely an example, and the material of the gate insulating layer 260 is not limited thereto.

The paraelectric layer 242 may include the first paraelectric layer portion 2421 and the second paraelectric layer portion 2422. The first paraelectric layer portion 2421 may be positioned inside the interlayer insulating layer 112. For example, the first paraelectric layer portion 2421 may be formed on the inner side surface of the interlayer insulating layer 112. The first paraelectric layer portion 2421 may be positioned between two gate electrodes 111 positioned adjacent to each other in the vertical direction D3. For example, the first paraelectric layer portion 2421 may be positioned in a recessed portion of the unevenness formed by the gate electrode 111 and the interlayer insulating layer 112. The second paraelectric layer portion 2422 may extend inward from the first paraelectric layer portion 2421. The second paraelectric layer portion 2422 may be positioned between the first paraelectric layer portion 2421 and the channel insulating layer 230. For example, the second paraelectric layer portion 2422 may have a thickness greater than that of the first paraelectric layer portion 2421.

A thickness of a thickest portion of the paraelectric layer 242 may be greater than a thickness of the interlayer insulating layer 112. For example, the thickness of the second paraelectric layer portion 2422 may be greater than the thickness of the interlayer insulating layer 112. The thickness of the ferroelectric layer 241 may be smaller than the thickness of the gate electrode 111. However, this is merely an example, and the shape of the paraelectric layer 242 and/or the ferroelectric layer 241 is not limited thereto. For example, the thickness of the second paraelectric layer portion 2422 may be smaller than the thickness of the interlayer insulating layer 112, and the thickness of the ferroelectric layer 241 may be greater than the thickness of the gate electrode 111.

The contents described above with reference to FIG. 5 and/or FIG. 7 are applied to the remaining components of the channel structure 200-2 described above with reference to FIG. 9B within a range not contradicting each other.

FIG. 9C is an enlarged cross-sectional view illustrating a channel structure of a semiconductor device according to at least one. FIG. 9C is an enlarged view of an area corresponding to the area C of FIG. 4 in the semiconductor device.

Referring to FIG. 9C, a channel structure 200-3 may include the core insulating layer 210, the channel poly layer 220, the crystalline layer 240, and the gate insulating layer 260. The channel structure 200-3 described with reference to FIG. 9C may be a structure in which the channel insulating layer 230 and the electron trap layer 250 are omitted from the channel structure 200 and/or 200′ described with reference to FIG. 5 and/or FIG. 7. The plurality of gate insulating layers 260 may be positioned between the crystalline layer 240 and the plurality of gate electrodes 111 at a height corresponding to the plurality of gate electrodes 111. In the case of the channel structure 200-3 described with reference to FIG. 9C, the channel poly layer 220 and/or the gate insulating layer 260 positioned on both sides of the ferroelectric layer 241 may stabilize the remanent polarization of the ferroelectric layer 241. For example, at least a portion of the channel poly layer 220 and/or the gate insulating layer 260 positioned adjacent to the ferroelectric layer 241 may be polarized in a direction that conforms to the remanent polarization direction of the ferroelectric layer 241, thereby stabilizing the remanent polarization state of the ferroelectric layer 241. For example, the gate insulating layer 260 may include a Low-K material having a low dielectric constant. The Low-K material may refer to a material having a dielectric constant of 4F/m or less. However, this is merely an example, and the material of the gate insulating layer 260 is not limited thereto.

The paraelectric layer 242 may include the first paraelectric layer portion 2421 and the second paraelectric layer portion 2422. The first paraelectric layer portion 2421 may be positioned inside the interlayer insulating layer 112. For example, the first paraelectric layer portion 2421 may be formed on the inner side surface of the interlayer insulating layer 112. The first paraelectric layer portion 2421 may be positioned between two gate electrodes 111 positioned adjacent to each other in the vertical direction D3. For example, the first paraelectric layer portion 2421 may be positioned in a recessed portion of the unevenness formed by the gate electrode 111 and the interlayer insulating layer 112. The second paraelectric layer portion 2422 may extend inward from the first paraelectric layer portion 2421. The second paraelectric layer portion 2422 may be positioned between the first paraelectric layer portion 2421 and the channel poly layer 220. For example, the second paraelectric layer portion 2422 may have a thickness greater than that of the first paraelectric layer portion 2421.

A thickness of a thickest portion of the paraelectric layer 242 may be greater than a thickness of the interlayer insulating layer 112. For example, the thickness of the second paraelectric layer portion 2422 may be greater than the thickness of the interlayer insulating layer 112. The thickness of the second paraelectric layer portion 2422 may be greater than the thickness of the first paraelectric layer portion 2421. The thickness of the ferroelectric layer 241 may be smaller than the thickness of the gate electrode 111. However, this is merely an example, and the shape of the paraelectric layer 242 and/or the ferroelectric layer 241 is not limited thereto. For example, the thickness of the second paraelectric layer portion 2422 may be smaller than the thickness of the interlayer insulating layer 112, and the thickness of the ferroelectric layer 241 may be greater than the thickness of the gate electrode 111.

The contents described above with reference to FIG. 5 and/or FIG. 7 are applied to the remaining components of the channel structure 200-3 described above with reference to FIG. 9C within a range not contradicting each other.

The manufacturing method described above with reference to FIGS. 6A to 6G and/or the manufacturing method described above with reference to FIGS. 8A to 8C are applied to the method of manufacturing the channel structure described with reference to FIG. 9A, FIG. 9B, and/or FIG. 9C. It will be easily understood by those skilled in the art that the channel structure described with reference to FIG. 9A, FIG. 9B, and/or FIG. 9C may be manufactured by omitting the operation of forming some components (e.g., the electron trap layer 250 and/or the channel insulating layer 230) from the manufacturing method described above with reference to FIGS. 6A to 6G and/or the manufacturing method described above with reference to FIGS. 8A to 8C.

As described above, although the examples have been described with reference to the limited drawings, a person skilled in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents of the claims are within the scope of the following claims.

What is claimed is:

1. A semiconductor device comprising:
a substrate;
a stacked structure comprising a plurality of gate electrodes and a plurality of interlayer insulating layers alternately stacked on the substrate; and
a plurality of channel structures penetrating the stacked structure,
wherein each of the plurality of channel structures comprises
a channel poly layer,
a crystalline layer outside the channel poly layer and comprising at least one of hafnium (Hf) or zirconium (Zr),
an electron trap layer outside the crystalline layer such that the crystalline layer is between the electron trap layer and the channel poly layer, and
a plurality of gate insulating layers between the electron trap layer and the plurality of gate electrodes at heights corresponding to the plurality of gate electrodes,
wherein the crystalline layer comprises
a plurality of ferroelectric layers each at a height corresponding to one of the plurality of gate electrodes, and
a plurality of paraelectric layers each at a height corresponding to one of the plurality of interlayer insulating layers, and
the plurality of ferroelectric layers and the plurality of paraelectric layers have different crystal structures while containing the same material.

2. The semiconductor device of claim 1, wherein an inner end portion of each of the plurality of interlayer insulating layers protrudes toward a center of a corresponding one of the plurality of channel structures from an inner end portion of a corresponding one of the plurality of gate electrodes.

3. The semiconductor device of claim 2, wherein
the inner end portion of the corresponding gate insulating layer protrudes inward further than the inner end portion of corresponding interlayer insulating layer, and
an outer end portion of the corresponding gate insulating layer is further outward compared to the inner end portion of the corresponding interlayer insulating layer.

4. The semiconductor device of claim 3, wherein
the electron trap layer comprises a plurality of first electron trap layer portions at heights corresponding to the plurality of gate electrodes, and a plurality of second electron trap layer portions positioned at heights corresponding to the plurality of interlayer insulating layers, and
the plurality of first electron trap layer portions is further inward compared to the plurality of second electron trap layer portions.

5. The semiconductor device of claim 1, wherein a radius from a center of each of the plurality of channel structures to an outer end portion of the plurality of paraelectric layers is greater than a radius from the center of the channel structure to an outer end portion of the plurality of ferroelectric layers.

6. The semiconductor device of claim 5, wherein a difference between the radius from the center of the channel structure to the outer end portion of the plurality of paraelectric layers and the radius from the center of the channel structure to the outer end portion of the plurality of ferroelectric layers is 30 Å or less.

7. The semiconductor device of claim 5, wherein a difference between the radius from the center of the channel structure to the outer end portion of the plurality of paraelectric layers and the radius from the center of the channel structure to the outer end portion of the plurality of ferroelectric layers is within a range of 100 Å and 300 Å.

8. The semiconductor device of claim 1, wherein a thickness of the ferroelectric layer, in a vertical direction, is greater than a thickness of the gate electrode.

9. The semiconductor device of claim 4, wherein each of the plurality of paraelectric layers comprises:
a first paraelectric layer portion defined by a corresponding one of the plurality of second electron trap layer portions; and
a second paraelectric layer portion extending inward from a corresponding one of the plurality of first paraelectric layer portion and having a thickness, in a vertical direction, greater than a thickness of the first paraelectric layer portion.

10. The semiconductor device of claim 9, wherein the thickness of the second paraelectric layer portion, in a vertical direction, is smaller than a thickness of the corresponding interlayer insulating layer.

11. The semiconductor device of claim 1, wherein
the plurality of ferroelectric layers have orthorhombic crystal structures, and
the plurality of paraelectric layer have monoclinic crystal structures.

12. The semiconductor device of claim 1, wherein the crystalline layer comprises at least one of Hf₁₋ₓZrₓO₂ (0≤x≤1) or doped Hf₁₋ₓZrₓO₂ (0≤x≤1) doped with at least one of aluminum (Al), carbon (C), nitrogen (N), gadolinium (Gd), yttrium (Y), tantalum (Ta), lanthanum (La), or silicon (Si).

13. The semiconductor device of claim 1, further comprising:
a channel insulating layer between the channel poly layer and the crystalline layer.

14. The semiconductor device of claim 13, wherein the channel insulating layer comprises a high-k material.

15. The semiconductor device of claim 1, wherein a thickness, in a vertical direction, of each of the plurality of gate insulating layers is the same as a thickness of a corresponding one of the plurality of gate electrodes.

16. A semiconductor device comprising:
a substrate;
a stacked structure comprising a plurality of gate electrodes and a plurality of interlayer insulating layers alternately stacked on the substrate; and
a plurality of channel structures penetrating the stacked structure,
wherein each of the plurality of channel structures comprises
a channel poly layer,
a crystalline layer outside the channel poly layer and comprising at least one of hafnium (Hf) or zirconium (Zr), and
a plurality of gate insulating layers between the crystalline layer and the plurality of gate electrodes at heights corresponding to the plurality of gate electrodes,
wherein the crystalline layer comprises
a plurality of ferroelectric layers each at a height corresponding to the plurality of gate electrodes, and
a plurality of paraelectric layers each at a height corresponding to the plurality of interlayer insulating layers, and
the plurality of ferroelectric layers and the plurality of paraelectric layers have different crystal structures while containing the same material.

17. The semiconductor device of claim 16, wherein an inner end portion of each of the plurality of interlayer insulating layers protrudes toward a center of a corresponding one of the plurality of channel structures from an inner end portion of a corresponding one of the plurality of gate electrodes.

18. The semiconductor device of claim 17, wherein
the inner end portion of the corresponding gate insulating layers protrudes further inward further than the inner end portion of the plurality of interlayer insulating layers, and
an outer end portion of the corresponding gate insulating layers is further outward compared to the inner end portion of the corresponding interlayer insulating layer.

19. The semiconductor device of claim 16, wherein a radius from a center of each of the plurality of channel structure to an outer end portion of the plurality of paraelectric layers is greater than a radius from the center of the channel structure to an outer end portion of the plurality of ferroelectric layers.

20. The semiconductor device of claim 16, wherein each of the plurality of paraelectric layers comprises:
a first paraelectric layer portion inside the interlayer insulating layer; and
a second paraelectric layer portion extending inward from the first paraelectric layer portion and having a thickness, in a vertical direction, greater than a thickness of the first paraelectric layer portion.
